(19) United States
(12) Patent Application Publication
(10) Pub. No.: US 2017/0098637 A1
(43) Pub. Date: Apr. 6, 2017

(54) CIRCUIT MODULE AND METHOD FOR MANUFACTURING THE SAME

(71) Applicant: Murata Manufacturing Co., Ltd., Nagaokakyo-shi (JP)

(72) Inventor: Shu HAMADA, Nagaokakyo-shi (JP)

(21) Appl. No.: 15/379,555

(22) Filed: Dec. 15, 2016

Related U.S. Application Data
(63) Continuation of application No. PCT/JP2015/066755, filed on Jun. 10, 2015.

(30) Foreign Application Priority Data
Jun. 20, 2014 (JP) 2014-127342

(51) Int. Cl. H01L 25/18; H01L 23/29; H01L 21/78; H01L 23/552; H01L 25/04; H01L 23/528; H01L 21/56; H01L 23/31

(52) U.S. Cl. CPC H01L 25/18; H01L 21/561; H01L 23/29; H01L 23/3121; H01L 23/552; H01L 25/04; H01L 23/5283; H01L 21/78

(57) ABSTRACT

A module board includes insulating layers, ground electrodes, signal electrodes, and interlayer vias. Electronic components are mounted on a front surface of the module board, and a sealing resin layer covers the electronic components. A half-cut portion is provided in the module board at an outer peripheral edge thereof and recessed to an intermediate position in a thickness direction of the module board. A shield layer cover the sealing resin layer. The shield layer includes a frame portion that extends into the half-cut portion. The frame portion is electrically connected to ground interlayer vias that are exposed at an end surface and a bottom surface of the half-cut portion.

### CROSS REFERENCE TO RELATED APPLICATIONS

This application claims the benefit of priority to Japanese Patent Application No. 2014-127342 filed on Jun. 20, 2014 and is a Continuation application of PCT Application No. PCT/JP2015/066755 filed on Jun. 10, 2015. The entire contents of each application are hereby incorporated herein by reference.

### BACKGROUND OF THE INVENTION

1. Field of the Invention

The present invention relates to a circuit module in which an electronic component is mounted and a method for manufacturing the circuit module.

2. Description of the Related Art

A known circuit module has a structure in which an electronic component is mounted on a surface of a board, an insulating resin is provided so that the electronic component is embedded therein, and the insulating resin is covered with a conductive shield layer (see, for example, Japanese Unexamined Patent Application Publication No. 2004-172176). In such a circuit module, the shield layer reduces the risk of entrance of electromagnetic waves from the outside and leakage of electromagnetic waves to the outside.

In the circuit module described in Japanese Unexamined Patent Application Publication No. 2004-172176, a half-cut groove formed when the board is half-cut is covered with a shield layer, so that an internal electrode (inner layer pattern) formed in the board comes into contact with the shield layer in the half-cut groove and is connected to the ground. However, it tends to be difficult to form a half-cut groove having an exact depth depending on, for example, the processing accuracy. When the board has a small thickness, there is a risk that the internal electrode will not be exposed in the half-cut groove if the half-cut groove is too shallow, and there is a risk that the board will break if the half-cut groove is too deep. In addition, when the internal electrode has a small thickness, the contact area between the shield layer and the internal electrode at an end surface of the board is small. Therefore, the connection reliability between the shield layer and the ground is reduced, and the shielding effect is also reduced.

### SUMMARY OF THE INVENTION

Preferred embodiments of the present invention provide a circuit module in which connection reliability between a shield layer and ground is increased and which has sufficient shielding effect, and provide a method for manufacturing the circuit module.

A circuit module according to a preferred embodiment of the present invention includes a module board on which an electronic component is mounted at a front-surface side; an interlayer via provided at a position shifted from an outer peripheral edge of the module board toward a central region of the module board, the interlayer via having a ground potential; an insulating sealing resin layer provided on a front surface of the module board so that the electronic component is embedded in the sealing resin layer; a half-cut portion located at the outer peripheral edge of the module board and recessed from the front surface of the module board to an intermediate position in a thickness direction of the module board so that a portion of the interlayer via is exposed in the half-cut portion; and a conductive shield layer provided at the front surface of the module board so as to cover the sealing resin layer, the conductive shield layer including a portion that extends into the half-cut portion and that is electrically connected to the interlayer via.

According to a preferred embodiment of the present invention, a portion of the interlayer via is exposed in the half-cut portion located at the outer peripheral edge of the module board. Therefore, a portion of the shield layer provided at the front surface of the module board extends into the half-cut portion and is in contact with the interlayer via. As a result, the shield layer is able to be electrically connected to the interlayer via, so that the shield layer is able to be connected to the ground through the interlayer via. Thus, the connection reliability between the shield layer and the ground is able to be increased, and sufficient shielding effect is obtained.

According to a preferred embodiment of the present invention, a front-surface-side ground electrode having the ground potential is provided on the front surface of the module board, a conductive joining material is provided on the front-surface-side ground electrode, and a portion of the conductive joining material is exposed and electrically connected to the shield layer at a position where the portion of the conductive joining material faces the half-cut portion.

According to a preferred embodiment of the present invention, since a portion of the conductive joining material provided on the front-surface-side ground electrode is exposed at a position where the portion of the conductive joining material faces the half-cut portion, the conductive joining material is able to be electrically connected to the shield layer through the exposed portion thereof. As a result, the shield layer is able to be connected to the ground not only through the interlayer via but also through the conductive joining material. Thus, the connection reliability between the shield layer and the ground is higher than that in the case where the conductive joining material is not provided.

A method for manufacturing a circuit module according to a preferred embodiment of the present invention includes a first step of preparing a collective board to be divided into a plurality of daughter boards on which electronic components are mounted, the collective board including interlayer vias at positions shifted from dividing lines, which are boundary lines between regions of the daughter boards, toward the daughter-board side, the interlayer vias having a ground potential; a second step of forming an insulating sealing resin layer on a front surface of the collective board so that the electronic components are embedded in the sealing resin layer; a third step of cutting the collective board having the sealing resin layer formed thereon from a front-surface side, thus cutting through the sealing resin layer and half-cutting the collective board to an intermediate position in a thickness direction of the collective board so that portions of the interlayer vias are exposed; a fourth step of forming a conductive shield layer at the front-surface side of the half-cut collective board so that the shield layer is electrically connected to the interlayer vias; and a fifth step of cutting the collective board having the shield layer formed thereon along the dividing lines, thus obtaining a plurality of circuit modules structured such that the electronic components are shielded by the shield layer.

According to a preferred embodiment of the present invention, the interlayer vias having the ground potential are arranged on the collective board at positions shifted from the dividing lines toward the daughter-board side. Accordingly, when the collective board is half-cut along the dividing lines, portions of the interlayer vias are able to be exposed at the end surfaces or the bottom surface of half-cut grooves formed in the collective board. Therefore, by forming the conductive shield layer at the front-surface side of the half-cut collective board, the shield layer is able to be brought into contact with the interlayer vias. As a result, the shield layer is able to be electrically connected to the interlayer vias, and therefore is able to be connected to the ground through the interlayer vias. Accordingly, the connection reliability between the shield layer and the ground is able to be increased, and sufficient shielding effect is obtained.

The interlayer vias extend in the thickness direction of the collective board. Therefore, when the collective board is half-cut from the front-surface side thereof to an intermediate position in the thickness direction of the collective board, portions of the interlayer vias are exposed in the half-cut grooves irrespective of the depth of the half-cut grooves. Therefore, it is not necessary for the half-cut grooves to have an exact depth, and the manufacturing cost of the circuit module is able to be significantly reduced.

According to a preferred embodiment of the present invention, a front-surface-side ground electrode having a ground potential is provided on the front surface of the collective board. When the electronic components are mounted on the collective board, a conductive joining material is applied to the front-surface-side ground electrode in addition to positions corresponding to the electronic components at the front surface of the collective board. In the third step, a portion of the conductive joining material applied to the front-surface-side ground electrode is exposed when the collective board is half-cut. In the fourth step, the shield layer is electrically connected to the interlayer vias and the conductive joining material.

According to a preferred embodiment of the present invention, the conductive joining material is applied to the front-surface-side ground electrode. Therefore, when the collective board is half-cut, not only can the portions of the interlayer vias be exposed in the half-cut grooves, but a portion of the conductive joining material applied to the front-surface-side ground electrode is also exposed in the half-cut grooves. Therefore, when the conductive shield layer is formed at the front-surface side of the half-cut collective board, the shield layer is able to be electrically connected not only to the interlayer vias but also to the conductive joining material. As a result, the shield layer is able to be connected to the ground not only through the ground interlayer vias but also through the conductive joining material, and the connection reliability between the shield layer and the ground is higher than that in the case where the conductive joining material is not provided.

When the electronic components are mounted on the collective board, the conductive joining material is applied to the front-surface-side ground electrode in addition to positions corresponding to the electronic components at the front surface of the collective board. Thus, the conductive joining material may be used to join the electronic components to the collective board, and may also be fixed to the front-surface-side ground electrode. Accordingly, the conductive joining material is able to be applied to the front-surface-side ground electrode at the time when the electronic components are mounted on the board, and it is not necessary to perform an additional step for applying the conductive joining material. Therefore, the yield is as high as that in the case where the conductive joining material is not applied to the front-surface-side ground electrode. In addition, since the connection reliability between the shield layer and the ground is able to be increased by using the conductive joining material for mounting the electronic components, the manufacturing cost is lower than that in the case where a connecting component different from that for the electronic components, for example, is used.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a sectional view of a circuit module according to a first preferred embodiment of the present invention.

FIG. 2 is a plan view of the circuit module viewed in the direction of line II-II in FIG. 1.

FIG. 3 is a plan view of the circuit module viewed from the same position as in FIG. 2, illustrating the state in which a shield layer is removed.

FIG. 4 is a plan view of a collective board used in a method for manufacturing the circuit module according to the first preferred embodiment of the present invention.

FIG. 5 is a sectional view viewed in the direction of line V-V in FIG. 4, illustrating a collective-board preparation step.

FIG. 6 is a sectional view taken at the same position as in FIG. 5, illustrating a sealing-resin-layer forming step.

FIG. 7 is a sectional view taken at the same position as in FIG. 5, illustrating a half-cutting step.

FIG. 8 is a sectional view taken at the same position as in FIG. 5, illustrating a shield-layer forming step.

FIG. 9 is a sectional view of a circuit module according to a second preferred embodiment of the present invention.

FIG. 10 is a sectional view illustrating a step of applying a conductive joining material to a collective board.

FIG. 11 is a sectional view taken at the same position as in FIG. 10, illustrating a component-mounting step.

FIG. 12 is a sectional view taken at the same position as in FIG. 10, illustrating a sealing-resin-layer forming step.

FIG. 13 is a sectional view taken at the same position as in FIG. 10, illustrating a half-cutting step.

FIG. 14 is a sectional view taken at the same position as in FIG. 10, illustrating a shield-layer forming step.

FIG. 15 is a plan view of a circuit module according to a modification of a preferred embodiment of the present invention, viewed from the same position as in FIG. 2.

### DETAILED DESCRIPTION OF THE PREFERRED EMBODIMENTS

Circuit modules according to preferred embodiments of the present invention will be described in detail with reference to the drawings.

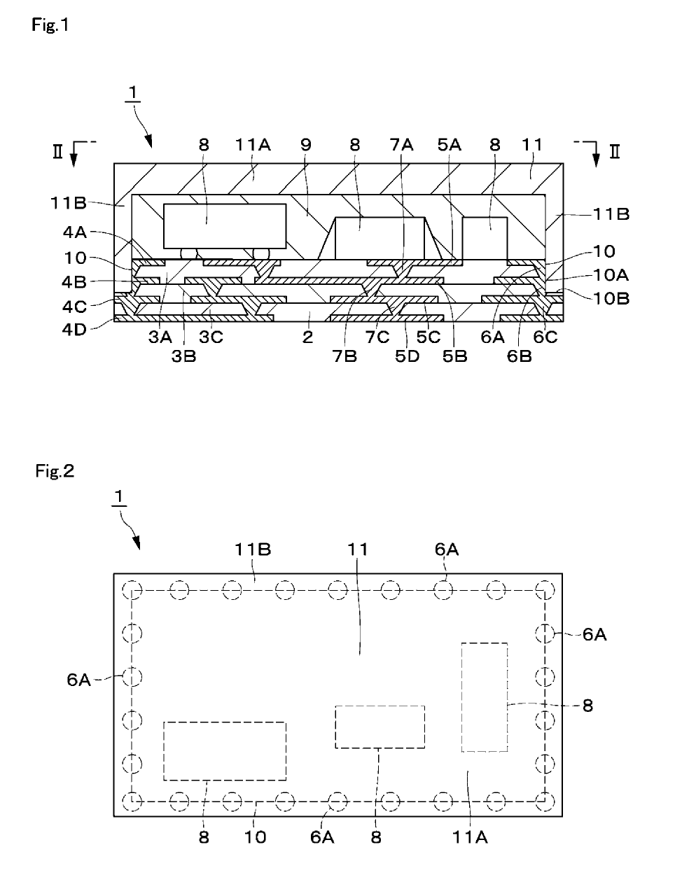

FIGS. 1 to 9 illustrate a first preferred embodiment of the present invention. A circuit module 1 according to the first preferred embodiment includes a module board 2, electronic components 8, a sealing resin layer 9, a half-cut portion 10, and a shield layer 11.

The module board 2 includes insulating layers 3A to 3C, ground electrodes 4A to 4D, signal electrodes 5A to 5D, and interlayer vias 6A to 6C and 7A to 7C. The front surface of the module board 2 defines and functions as a component mounting surface on which the electronic components 8 are mounted. The total thickness of the module board 2 is, for example, about 0.1 mm or more and about 1.0 mm or less.

The module board 2 includes a plurality of insulating layers (for example, three insulating layers) 3A to 3C. The insulating layers 3A to 3C are preferably made of a thermosetting resin containing, for example, an epoxy resin as the main component, a thermoplastic resin, etc., and are laminated together. The thickness of the insulating layers 3A to 3C is preferably in the range of, for example, about 5 μm or more and about 200 μm or less. The material of the insulating layers 3A to 3C is not limited to an organic material, such as resin, and may instead be an inorganic material, such as a ceramic material. Although an example in which the module board 2 includes three insulating layers 3A to 3C is described, the module board 2 may instead include a single insulating layer, two insulating layers, or four or more insulating layers.

The module board 2 includes a plurality of conductive layers (for example, four conductive layers) including the ground electrodes 4A to 4D and the signal electrodes 5A to 5D. The conductive layers and the insulating layers 3A to 3C are alternately stacked. The ground electrodes 4A to 4D and the signal electrodes 5A to 5D include thin films made of a conductive metal material, such as copper. The thickness of the ground electrodes 4A to 4D and the signal electrodes 5A to 5D is preferably in the range of, for example, about 5 μm or more and about 35 μm or less.

Although the ground electrodes 4A to 4D and the signal electrodes 5A to 5D are provided on the same conductive layers in the above-described structure, the ground electrodes and the signal electrodes may be arranged at different positions in the thickness direction so as to define different conductive layers. The number of conductive layers is not limited to four, and may instead be two, three, or five or more, for example.

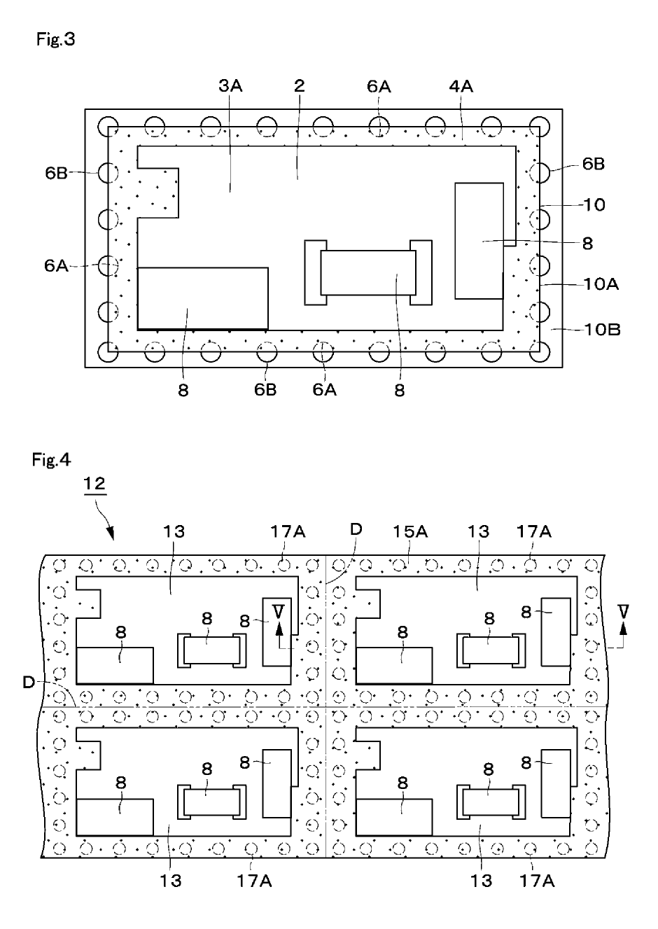

As illustrated in FIG. 1, the ground electrode 4A is provided on the front surface of the module board 2 (insulating layer 3A), and defines a front-surface-side ground electrode. As illustrated in FIG. 3, the ground electrode 4A is, for example, frame-shaped and surrounds the outer peripheral edge of the module board 2. The end portions of the ground electrode 4A at the outer peripheral edge extend to the half-cut portion 10. The ground electrode 4B is located between the insulating layers 3A and 3B, and the ground electrode 4C is located between the insulating layers 3B and 3C. Thus, the ground electrodes 4B and 4C are disposed inside the module board 2. The ground electrode 4D is located on the back surface of the module board 2 (insulating layer 3C), and is connectable to an external ground. The ground electrodes 4A to 4D are connected to each other by the ground interlayer vias 6A to 6C (interlayer vias 6A to 6C), which connect the conductive layers at different positions in the thickness direction. Accordingly, the ground electrodes 4A to 4D are maintained at the ground potential.

The structure of the signal electrodes 5A to 5D is similar to that of the ground electrodes 4A to 4D. The signal electrode 5A is located on the front surface of the module board (insulating layer 3A), and the electronic components 8, which will be described below, are joined to the signal electrode 5A. The signal electrode 5B is located between the insulating layers 3A and 3B, and the signal electrode 5C is located between the insulating layers 3B and 3C. The signal electrode 5D is located on the back surface of the module board 2 (insulating layer 3C), and is connectable to, for example, an external signal line. The signal electrodes 5A to 5D are connected to each other by the signal interlayer vias 7A to 7C, which connect the conductive layers at different positions in the thickness direction. Thus, the signal electrodes 5A to 5D supply various signals, a drive voltage, etc., to the electronic components 8, which will be described below.

The ground interlayer vias 6A to 6C are provided in the insulating layers 3A to 3C, and electrically connect the ground electrodes 4A to 4D to each other. More specifically, the interlayer vias 6A extend through the insulating layer 3A and connect the ground electrodes 4A and 4B to each other. The interlayer vias 6B extend through the insulating layer 3B and connect the ground electrodes 4B and 4C to each other. The interlayer vias 6C extend through the insulating layer 3C and connect the ground electrodes 4C and 4D to each other.

The ground interlayer vias 6A to 6C are preferably formed by, for example, forming through holes that extend through the insulating layers 3A to 3C by laser processing or the like, and then plating the through holes with copper or applying a conductive paste or the like to the through holes. As illustrated in FIG. 2, a plurality of interlayer vias 6A to 6C are arranged in lines parallel or substantially parallel to the outer peripheral edge of the module board 2 at positions shifted from the outer peripheral edge of the module board 2 toward the central region. The interval between two adjacent interlayer vias 6A in the same layer is preferably set to, for example, about 100 μm or more and about 1000 μm or less. The interval between two adjacent interlayer vias 6B in the same layer and the interval between two adjacent interlayer vias 6C in the same layer are also set to a value similar to the interval between two adjacent interlayer vias 6A.

The outer diameter of the interlayer vias 6A to 6C is, for example, about several tens to several hundreds of micrometers. In the case where the interlayer vias 6A to 6C are formed of copper plating, the plating thickness is preferably greater than or equal to, for example, about 5 μm. The plated holes of the interlayer vias 6A to 6C may be either filled or not filled.

The interlayer vias 6A to 6C are aligned in, for example, the thickness direction of the module board 2. The interlayer vias 6A to 6C are not necessarily aligned in the thickness direction, and may be disposed at different positions for each of the insulating layers 3A to 3C. At least one of the interlayer vias 6A to 6C is partially exposed in the half-cut portion 10, which will be described below.

The structure of the signal interlayer vias 7A to 7C is similar to that of the ground interlayer vias 6A to 6C. The signal interlayer vias 7A to 7C are provided in the insulating layers 3A to 3C, and electrically connect the signal electrodes 5A to 5D to each other. More specifically, the signal interlayer vias 7A extend through the insulating layer 3A and connect the signal electrodes 5A and 5B to each other. The signal interlayer vias 7B extend through the insulating layer 3B and connect the signal electrodes 5B and 5C to each other. The signal interlayer vias 7C extend through the insulating layer 3C and connect the signal electrodes 5C and 5D to each other.

The electronic components 8 are provided on the front surface of the module board 2, and include, for example, a semiconductor device, a capacitor, an inductor, and a resistor. The electronic components 8 are joined to the signal electrodes 5A, which are provided on the front surface of the module board 2, by using a conductive joining material, such as solder. Thus, the electronic components 8 and the signal electrodes 5A to 5D define an electronic circuit.

The sealing resin layer 9 is provided on the front surface of the module board 2, and the electronic components 8 are embedded in the sealing resin layer 9. The sealing resin layer 9 is made of an insulating resin material, and seals the front surface of the module board 2.

As illustrated in FIG. 2, the half-cut portion 10 is provided along the outer peripheral edge of the module board 2. The half-cut portion 10 is recessed from the front surface of the module board 2 to an intermediate position in the thickness direction. More specifically, the half-cut portion 10 is formed so that the front-surface-side portion of the outer peripheral edge of the module board 2 is removed and the back-surface-side portion of the outer peripheral edge of the module board 2 remains. Accordingly, the back-surface-side portion of the module board 2 has the shape of a flange that protrudes outward by an amount corresponding to the size of the half-cut portion 10.

Some of the ground interlayer vias 6A to 6C are exposed at an end surface 10A or a bottom surface 10B of the half-cut portion 10 (see FIG. 1). More specifically, the ground electrodes 4A and 4B and the ground interlayer vias 6A and 6B are partially exposed at the end surface 10A or the bottom surface 10B of the half-cut portion 10. In addition to the ground interlayer vias 6A and 6B, the ground interlayer vias 6C may also be exposed in the half-cut portion 10.

The shield layer 11 is provided on the front surface of the module board 2 so as to cover the sealing resin layer 9. The shield layer 11 is made of a conductive resin material obtained by mixing conductive particles, such as silver or copper particles, with a binder, such as a resin material. The thickness of the shield layer 11 preferably is, for example, about 10 μm or more and about 300 μm or less. The shield layer 11 includes a top portion 11A that covers the top portion of the sealing resin layer and a frame portion 11B that surrounds the outer peripheral surface of the sealing resin layer 9 and extends into the half-cut portion 10.

The frame portion 11B of the shield layer 11 has, for example, a rectangular or substantially rectangular shape that corresponds to the external shape of the module board 2. The frame portion 11B of the shield layer 11 includes a proximal end portion that is connected to the outer peripheral edge of the top portion 11A, and a distal end portion that extends from the top portion 11A toward the back surface of the module board 2 in the thickness direction and that is in contact with the bottom surface 10B of the half-cut portion 10. Thus, the frame portion 11B is electrically connected to the ground electrodes 4A and 4B and the ground interlayer vias 6A and 6B that are exposed in the half-cut portion 10. Since the shield layer 11 is connected to the ground interlayer vias 6A and 6B and other components that are at the ground potential, the shield layer 11 is maintained at the ground potential. As a result, the shield layer 11 shields the electronic components 8 from electric field noise and electromagnetic wave noise.

The material of the shield layer 11 is not limited to a conductive resin material, and may instead be, for example, a metal film formed by plating or the like.

A non-limiting example of a method for manufacturing the circuit module 1 will be described with reference to FIGS. 4 to 8.

FIGS. 4 and 5 illustrate a collective-board preparation step as a first step. In the collective-board preparation step, a collective board 12 including a plurality of daughter boards 13, which are arranged in a matrix, is prepared. As described below, the collective board 12 is cut along dividing lines D so that the daughter boards 13, on which the electronic components 8 are mounted, are separated from each other and the circuit module 1 is obtained. Accordingly, the dividing lines D define and function as boundary lines between the regions of the daughter boards 13. Each daughter board 13 corresponds to the module board 2 of the circuit module 1.

The collective board 12 is preferably formed by stacking insulating layers 14A to 14C and conductive layers including ground electrodes 15A to 15D and signal electrodes 16A to 16D. Ground interlayer vias 17A to 17C and signal interlayer vias 18A to 18C are provided in the insulating layers 14A to 14C. The ground electrodes 15A to 15D are electrically connected to each other by the ground interlayer vias 17A to 17C. The signal electrodes 16A to 16D are electrically connected to each other by the signal interlayer vias 18A to 18C. Here, the insulating layers 14A to 14C, the ground electrodes 15A to 15D, the signal electrodes 16A to 16D, the ground interlayer vias 17A to 17C, and the signal interlayer vias 18A to 18C respectively correspond to the insulating layers 3A to 3C, the ground electrodes 4A to 4D, the signal electrodes 5A to 5D, the ground interlayer vias 6A to 6C, and the signal interlayer vias 7A to 7C of the circuit module 1.

Here, the ground electrode 15A, which defines and functions as a front-surface-side ground electrode, is provided on the front surface of the collective board 12 so as to extend along, for example, the dividing lines D. The ground electrode 15A is provided on the collective board 12 so as to extend over two adjacent daughter boards 13 having a dividing line D therebetween. More specifically, the ground electrode 15A extends to positions shifted from the dividing lines D toward the daughter-board-13 side. The ground electrode 15A has a width that is greater than the width of a half-cut groove 20, which will be described below. Therefore, the ground electrode 15A partially remains on the front surface of the collective board 12 even after the half-cut groove 20 is formed. The ground interlayer vias 17A to 17C are arranged in the collective board 12 at positions shifted from the dividing lines D toward the daughter-board-13 side.

The electronic components 8 are mounted on the front surface of the collective board 12 by, for example, reflow soldering. More specifically, the electronic components 8 are mounted by, for example, applying solder paste to the signal electrodes 16A and placing the electronic components 8 onto the signal electrodes 16A so that the electronic components 8 come into contact with the solder paste. In this state, the collective board 12 is heated in a reflow oven so that the electronic components 8 are joined to the signal electrodes 16A.

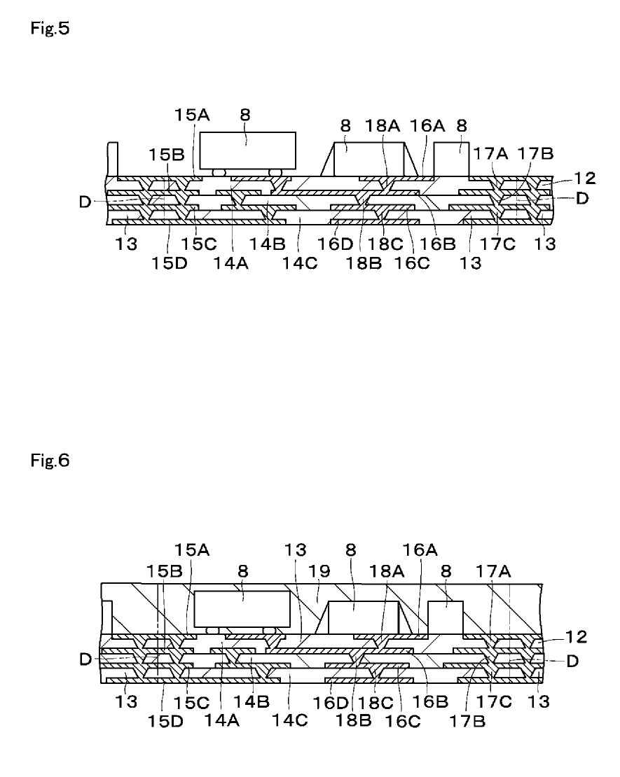

FIG. 6 illustrates a sealing-resin-layer forming step as a second step. In the sealing-resin-layer forming step, which is performed after the collective-board preparation step, a sealing resin layer 19, which is made of an insulating resin material, is formed on the front surface of the collective board 12 so as to cover the electronic components 8. More specifically, the sealing resin layer 19 is formed by applying the insulating resin material to the front surface of the collective board 12, curing the insulating resin material, and grinding the top portion of the insulating resin material. During this process, the electronic components 8 are embedded between the collective board 12 and the sealing resin layer 19. The sealing resin layer 19 corresponds to the sealing resin layer 9 of the circuit module 1.

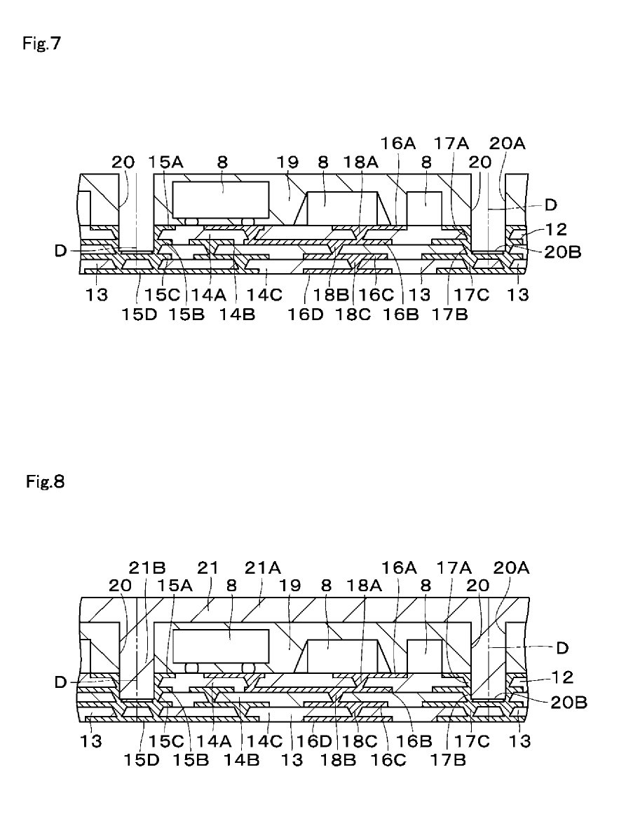

FIG. 7 illustrates a half-cutting step as a third step. In the half-cutting step, which is performed after the sealing-resin-layer forming step, the collective board 12 is half-cut from the front-surface side thereof along the dividing lines D of the daughter boards 13. More specifically, a dicer or the like is used to cut through the sealing resin layer 19 and into the collective board 12 to an intermediate position in the thickness direction of the collective board 12, so that the half-cut groove 20, which has, for example, a rectangular or substantially rectangular cross section, is formed in the collective board 12. The half-cut groove 20, for example, is formed so as to partially remove the ground interlayer vias 17A and 17B. Therefore, an end surface 20A of the half-cut groove 20 is located so as to intersect the ground interlayer vias 17A, for example, and extends in the thickness direction of the collective board 12. A bottom surface 20B of the half-cut groove 20 is separated from the back surface of the collective board 12, so that two adjacent daughter boards 13 are partially connected to each other at the back-surface side of the collective board 12. As a result, portions of the ground interlayer vias 17A and 17B are exposed at the end surface 20A and the bottom surface 20B of the half-cut groove 20.

In the case where the half-cut groove 20 has a small depth, the half-cut groove 20 may be formed such that only the ground interlayer vias 17A are exposed in the half-cut groove 20. In the case where the half-cut groove 20 has a large depth, the ground interlayer vias 17C may be exposed in the half-cut groove 20 in addition to the ground interlayer vias 17A and 17B.

FIG. 8 illustrates a shield-layer forming step as a fourth step. In the shield-layer forming step, which is performed after the sealing-resin-layer forming step, a conductive shield layer 21 is formed at the front-surface side of the collective board 12. More specifically, in the shield-layer forming step, a conductive resin material is applied so as to cover the sealing resin layer 19 and fill the half-cut groove 20, and is cured. Accordingly, the shield layer 21, which includes a top portion 21A that covers the top portion of the sealing resin layer 19 and a frame portion 21B that extends into the half-cut groove 20, is formed. The frame portion 21B that extends into the half-cut groove 20 comes into contact with and becomes electrically connected to some of the ground interlayer vias 17A to 17C that are exposed at the end surface 20A and the bottom surface 20B of the half-cut groove 20. The shield layer 21 corresponds to the shield layer 11 of the circuit module 1.

The material of the shield layer 21 is not limited to a conductive resin material, and may instead be a metal film. The shield layer 21 made of a metal film may be formed by plating, for example, at the front-surface side of the collective board 12 on which the sealing resin layer 19 is provided.

In a dividing step, which is a fifth step performed after the shield-layer forming step, the collective board 12 is cut along the dividing lines D by using a dicer or the like, so that the daughter boards 13 are separated from each other. The collective board 12 is cut along the dividing lines D by using a dicer having a width smaller than the width of the half-cut groove 20. Accordingly, the half-cut groove 20 is divided into two half-cut portions 10 having an L-shaped cross section along each dividing line D at the central position in the width direction. Thus, the collective board 12 is divided into the daughter boards 13, and a plurality of circuit modules 1, in each of which the electronic components 8 are shielded by the shield layer 21, are manufactured.

According to the first preferred embodiment, some of the ground interlayer vias 6A to 6C, for example, the ground interlayer vias 6A and 6B, are exposed in the half-cut portion 10 at the outer peripheral edge of the module board 2. Therefore, a portion of the shield layer 11, which is provided at the front surface of the module board 2, extends into the half-cut portion 10 and is in contact with the ground interlayer vias 6A and 6B. As a result, the shield layer 11 is able to be electrically connected to the ground interlayer vias 6A and 6B, so that the shield layer 11 is able to be connected to the ground through the ground interlayer vias 6A and 6B. Thus, in the circuit module 1, the contact area between the shield layer 11 and the ground interlayer vias 6A and 6B, which are at the ground potential, is greater than that in a circuit module that does not include the interlayer vias. Therefore, the connection reliability between the shield layer 11 and the ground is able to be increased, and sufficient shielding effect is obtained.

When the circuit module 1 is manufactured, the ground interlayer vias 17A to 17C, which are at the ground potential, are arranged on the collective board 12 at positions shifted from the dividing lines D toward the daughter-board-13 side. Accordingly, when the collective board 12 is half-cut along the dividing lines D, some of the ground interlayer vias 17A to 17C (for example, the interlayer vias 17A and 17B) are able to be exposed at the end surface 20A or the bottom surface 20B of the half-cut groove 20 formed in the collective board 12. Therefore, by forming the conductive shield layer 21 at the front-surface side of the half-cut collective board 12, the shield layer 21 is able to be brought into contact with the ground interlayer vias 17A and 17B, which are exposed in the half-cut groove 20. As a result, the shield layer 21 is able to be electrically connected to the ground interlayer vias 17A and 17B, and therefore is able to be connected to the ground through the ground interlayer vias 17A and 17B. Accordingly, the connection reliability between the shield layer 21 and the ground is able to be increased, and sufficient shielding effect is obtained.

The ground interlayer vias 17A to 17C extend in the thickness direction of the collective board 12. Therefore, when the collective board 12 is half-cut from the front-surface side thereof to an intermediate position in the thickness direction of the collective board 12, some of the ground interlayer vias 17A to 17C are exposed in the half-cut groove 20 irrespective of the depth of the half-cut groove 20. Accordingly, even when, for example, the accuracy of the depth of the half-cut groove 20 is reduced due to wearing of the teeth of the dicer, some of the ground interlayer vias 17A to 17C are able to be exposed in the half-cut groove 20 and connected to the shield layer 21. Therefore, it is not necessary for the half-cut groove 20 to have an exact depth, so that the yield is able to be increased and the manufacturing cost is able to be significantly reduced.

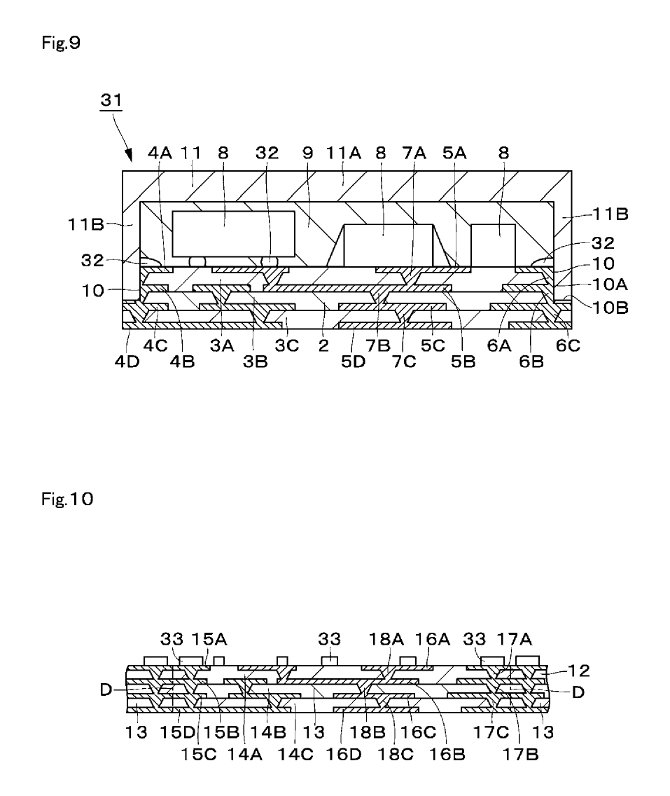

FIGS. 9 to 14 illustrate a second preferred embodiment of the present invention. The second preferred embodiment includes solder applied to the ground electrode and a shield layer connected to the solder. In the second preferred embodiment, components that are the same as those in the first preferred embodiment are denoted by the same reference numerals, and description thereof is omitted.

Similar to the circuit module 1 according to the first preferred embodiment, a circuit module 31 according to the second preferred embodiment includes the module board 2, the electronic components 8, the sealing resin layer 9, the half-cut portion 10, and the shield layer 11. In the circuit module 31, solder 32 is applied to the ground electrode 4A on the module board 2, and the solder 32 is connected to the shield layer 11. In this point, the circuit module 31 of the second preferred embodiment differs from the circuit module 1 of the first preferred embodiment.

The solder 32, which defines and functions as a conductive joining material, is provided above the ground electrode 4A and the ground interlayer vias 6A in the thickness direction. The solder 32 is applied so as to swell upward from the front surface of the module board 2 beyond the ground electrode 4A, and forms solder bumps or solder levelers. The height of the solder 32 is, for example, about 10 μm or more and about 200 μm or less.

A portion of the solder 32 is exposed at a position where the portion of the solder 32 faces the half-cut portion 10, and is electrically connected to the shield layer 11. The solder 32 is, for example, similar to the solder used to join the electronic components 8 to the module board 2. The solder 32 is maintained at the ground potential through the ground electrode 4A, which are at the ground potential. Thus, the solder 32 increases the connection reliability between the shield layer 11 and the ground.

Next, a non-limiting example of a method for manufacturing the circuit module 31 will be described with reference to FIGS. 10 to 14.

FIG. 10 illustrates a conductive-joining-material attaching step in which solder paste 33, which defines and functions as a conductive joining material, is applied to the collective board 12. In the conductive-joining-material attaching step, similar to the first preferred embodiment, the collective board 12 including the daughter boards 13, which are arranged in a matrix, is prepared. Then, the solder paste 33 is applied to the signal electrodes 16A and the ground electrode 15A provided on the front surface of the collective board 12. More specifically, the solder paste 33 is applied to the signal electrodes 16A at positions where the electronic components 8 are to be joined to the signal electrodes 16A. The solder paste 33 is also applied to the ground electrode 15A at positions corresponding to the positions of the ground interlayer vias 17A. The solder paste 33 is not necessarily applied at the positions corresponding to the positions of the ground interlayer vias 17A, and may be applied at any positions as long as, for example, the solder paste 33 partially remains after the half-cutting step described below.

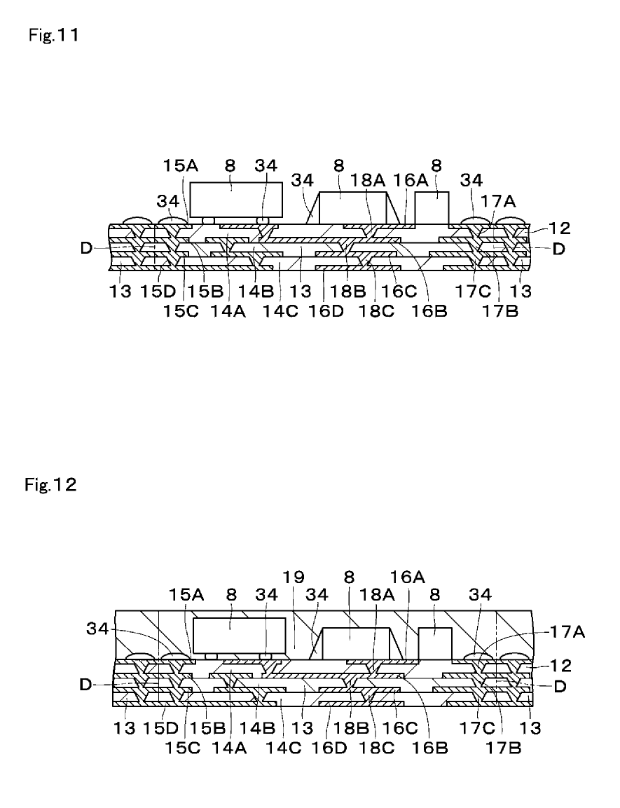

FIG. 11 illustrates a component-mounting step. The component-mounting step and the conductive-joining-material attaching step define a first step. In the component-mounting step, which is performed after the conductive-joining-material attaching step, the collective board 12 is heated in, for example, a reflow oven in the state in which the electronic components 8 are placed on the solder paste 33 on the collective board 12. Accordingly, the solder paste 33 is melted and then solidified, so that the electronic components 8 are joined to the signal electrodes 16A on the collective board 12. At this time, the solder paste 33 applied to the ground electrode 15A is also melted when heated, and is then solidified. Accordingly, solder 34, which protrudes from the front surface of the collective board 12, is formed on the ground electrode 15A at the positions corresponding to the positions of the ground interlayer vias 17A. The solder 34 corresponds to the solder 32 in the circuit module 31.

The ground interlayer vias 17A provided in the front surface of the collective board 12 tend to be recessed in central regions of circular or substantially circular openings thereof. Therefore, the solder 34 applied to the ground interlayer vias 17A do not needlessly spread to other regions, and is positioned around the ground interlayer vias 17A.

FIG. 12 illustrates a sealing-resin-layer forming step as a second step. In the sealing-resin-layer forming step, which is performed after the component-mounting step, similar to the first preferred embodiment, the sealing resin layer 19 is formed on the front surface of the collective board 12 so that the electronic components 8 and the solder 34 are embedded in the sealing resin layer 19.

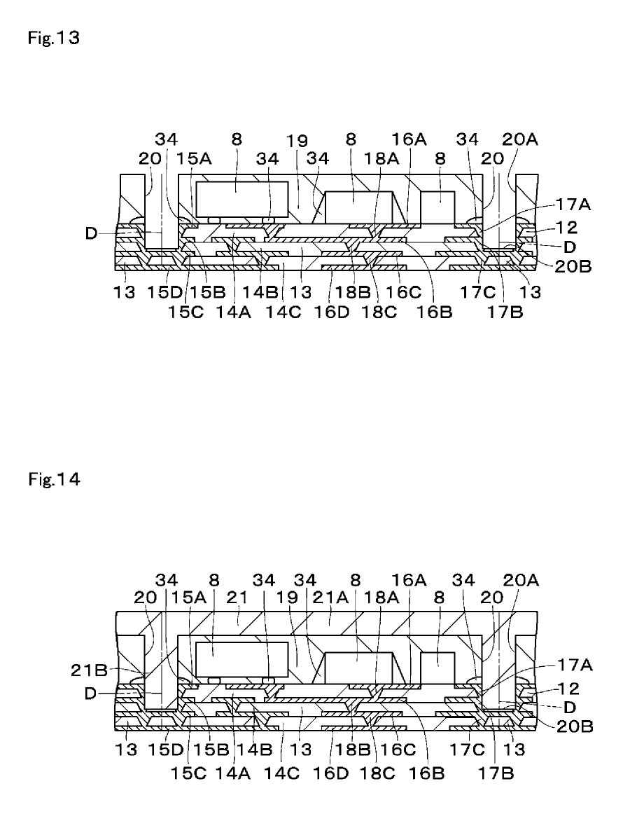

FIG. 13 illustrates a half-cutting step as a third step. In the half-cutting step, which is performed after the sealing-resin-layer forming step, similar to the first preferred embodiment, the collective board 12 is half-cut from the front-surface side thereof along the dividing lines D of the daughter boards 13. More specifically, a dicer or the like is used to cut through the sealing resin layer 19 and into the collective board 12 to an intermediate position in the thickness direction of the collective board 12, so that the half-cut groove 20 is formed in the collective board 12. When the collective board 12 is half-cut, the solder 34 provided on the ground electrode 15A is partially removed. As a result, a portion of the solder 34 is exposed at the end surface 20A or the bottom surface 20B of the half-cut groove 20.

FIG. 14 illustrates a shield-layer forming step as a fourth step. In the shield-layer forming step, which is performed after the sealing-resin-layer forming step, similar to the first preferred embodiment, the conductive shield layer 21 is formed at the front-surface side of the collective board 12. Accordingly, the shield layer 21, which fills the half-cut groove 20, comes into contact with and becomes electrically connected to the solder 34 and some of the ground interlayer vias 17A to 17C that are exposed at the end surface 20A and the bottom surface 20B of the half-cut groove 20.

In a dividing step, which is a fifth step performed after the shield-layer forming step, the collective board 12 is cut along the dividing lines D by using a dicer or the like, so that the daughter boards 13 are separated from each other. As a result, a plurality of circuit modules 31, in each of which the electronic components 8 are shielded by the shield layer 21, are manufactured.

Also in the second preferred embodiment, effects similar to those of the first preferred embodiment are obtained. Since a portion of the solder 32 provided on the ground electrode 4A is exposed at a position where the portion of the solder 32 faces the half-cut portion 10, the solder 32 is able to be electrically connected to the shield layer 11 through the exposed portion thereof. As a result, the shield layer 11 is able to be connected to the ground not only through the ground interlayer vias 6A and 6B but also through the solder 32. Thus, the connection reliability between the shield layer 11 and the ground is higher than that in the case where the solder 32 is not provided.

When the circuit module 31 is manufactured, the solder 34 is provided on the ground electrode 15A at positions shifted from the dividing lines D toward the daughter-board-13 side. Therefore, when the collective board 12 is half-cut, not only can some of the ground interlayer vias 17A to 17C be exposed in the half-cut groove 20, but a portion of the solder 34 applied to the ground electrode 15A is able to be exposed in the half-cut groove 20. Therefore, when the conductive shield layer 21 is formed at the front-surface side of the half-cut collective board 12, the shield layer 21 is able to be electrically connected not only to the ground interlayer vias 17A to 17C but also to the solder 34. As a result, the shield layer 21 is able to be connected to the ground not only through, for example, the ground interlayer vias 17A, but also through the solder 34, and the connection reliability between the shield layer 21 and the ground is able to be increased.

When the electronic components 8 are mounted on the collective board 12, the solder 34 is applied to the ground electrode 15A in addition to the positions corresponding to the electronic components 8 at the front surface of the collective board 12. Thus, the solder 34 may be used to join the electronic components 8 to the collective board 12, and may also be fixed to the ground electrode 15A. Accordingly, the solder 34 is able to be applied to the ground electrode 15A at the time when the electronic components 8 are mounted on the collective board 12, and it is not necessary to perform an additional step for applying the solder 34. Therefore, the yield is as high as that in the case where the solder 34 is not provided on the ground electrode 15A. In addition, since the connection reliability between the shield layer 21 and the ground is able to be increased by using the solder 34 for mounting the electronic components 8, the manufacturing cost is lower than that in the case where a connecting component different from that for the electronic components 8, for example, is used.

In the second preferred embodiment, the solder 32 is applied to the ground electrode 15A as the conductive joining material. However, the present invention is not limited to this, and any conductive joining material, such as a thermosetting conductive adhesive, may be used as long as the material is used to join the electronic components 8 to the module board 2.

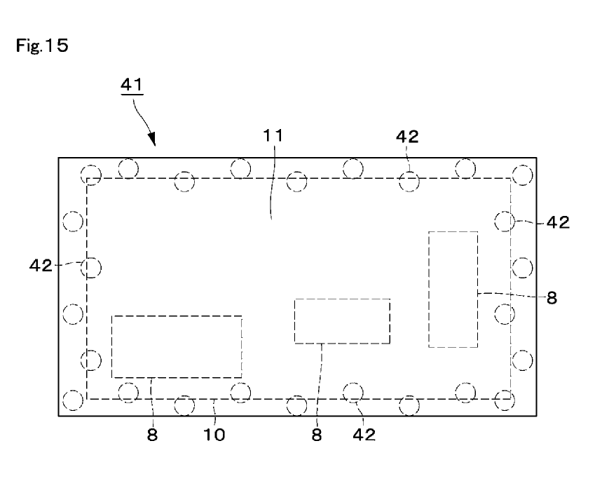

In each of the above-described preferred embodiments, the ground interlayer vias 6A are arranged in lines at positions shifted from the outer peripheral edge of the module board 2 toward the central region. However, the present invention is not limited to this, and the structure of a circuit module 41 according to a modification illustrated in FIG. 15, for example, may be used. In the circuit module 41, a plurality of ground interlayer vias 42 located at the front-surface side of the module board 2 are arranged in a zigzag pattern along the outer peripheral edge of the module board 2, and are located at different distances from the outer peripheral edge of the module board 2. In this case, the interlayer vias located below the ground interlayer vias 42 in the thickness direction of the module board 2 may either be aligned with the ground interlayer vias 42 in the thickness direction or be located at different positions when viewed in the thickness direction. The ground interlayer vias may be shifted in accordance with the positions at which the electronic components 8 are mounted.

Although a plurality of ground interlayer vias 6A are connected to the shield layer 11 in each of the above-described preferred embodiments, a single ground interlayer via 6A may instead be connected to the shield layer 11. Similarly, in the circuit modules 1 and 31, the number of ground interlayer vias 6B, the number of ground interlayer vias 6C, and the number of positions at which the solder 32 is applied may be one, two, or more.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. A circuit module comprising:
a module board on which an electronic component is mounted at a front-surface side;
an interlayer via provided at a position shifted from an outer peripheral edge of the module board toward a central region of the module board, the interlayer via having a ground potential;
an insulating sealing resin layer provided on a front surface of the module board so that the electronic component is embedded in the sealing resin layer;
a half-cut portion located at the outer peripheral edge of the module board and recessed from the front surface of the module board to an intermediate position in a thickness direction of the module board so that a portion of the interlayer via is exposed in the half-cut portion; and
a conductive shield layer provided at the front surface of the module board to cover the sealing resin layer, the conductive shield layer including a portion that extends into the half-cut portion and that is electrically connected to the interlayer via.

2. The circuit module according to claim 1, wherein
a front-surface-side ground electrode having the ground potential is provided on the front surface of the module board;
a conductive joining material is provided on the front-surface-side ground electrode; and
a portion of the conductive joining material is exposed and electrically connected to the shield layer at a position where the portion of the conductive joining material faces the half-cut portion.

3. The circuit module according to claim 1, wherein the module board includes insulating layers, ground electrodes, and signal electrodes.

4. The circuit module according to claim 3, wherein the ground electrodes and the signal electrodes are provided on the same ones of the insulating layers.

5. The circuit module according to claim 3, wherein one of the ground electrodes is frame-shaped and surrounds the outer peripheral edge of the module board.

6. The circuit module according to claim 1, wherein the electronic component includes at least one of a semiconductor, a capacitor, an inductor and a resistor.

7. The circuit module according to claim 1, wherein the electronic component includes a plurality of electronic components, and the module board includes signal electrodes defining an electronic circuit with the plurality of electronic components.

8. The circuit module according to claim 1, wherein the interlayer via is exposed in an end surface or a bottom surface of the half-cut portion.

9. The circuit module according to claim 1, wherein the shield layer is made of a conductive resin material.

10. The circuit module according to claim 1, wherein the shield layer surrounds an outer peripheral surface of the sealing resin layer.

11. The circuit module according to claim 1, wherein the shield layer is connected to the interlayer via.

12. The circuit module according to claim 1, wherein the interlayer via includes a plurality of interlayer vias arranged in lines as positions shifted from the outer peripheral edge of the module board toward to the central region.

13. The circuit module according to claim 1, wherein the interlayer via includes a plurality of interlayer vias arranged in a zig-zag pattern along the outer peripheral edge of the module board.

14. A method for manufacturing a circuit module, the method comprising:
a first step of preparing a collective board to be divided into a plurality of daughter boards on which electronic components are mounted, the collective board including interlayer vias at positions shifted from dividing lines, which are boundary lines between regions of the daughter boards, toward a daughter-board side, the interlayer vias having a ground potential;
a second step of forming an insulating sealing resin layer on a front surface of the collective board so that the electronic components are embedded in the sealing resin layer;
a third step of cutting the collective board having the sealing resin layer formed thereon from a front-surface side, thus cutting through the sealing resin layer and half-cutting the collective board to an intermediate position in a thickness direction of the collective board so that portions of the interlayer vias are exposed;
a fourth step of forming a conductive shield layer at the front-surface side of the half-cut collective board so that the shield layer is electrically connected to the interlayer vias; and
a fifth step of cutting the collective board having the shield layer formed thereon along the dividing lines, thus obtaining a plurality of circuit modules structured such that the electronic components are shielded by the shield layer.

15. The method according to claim 14, wherein
a front-surface-side ground electrode having a ground potential is provided on the front surface of the collective board;
when the electronic components are mounted on the collective board, a conductive joining material is applied to the front-surface-side ground electrode in addition to positions corresponding to the electronic components at the front surface of the collective board;
in the third step, a portion of the conductive joining material applied to the front-surface-side ground electrode is exposed when the collective board is half-cut; and
in the fourth step, the shield layer is electrically connected to the interlayer vias and the conductive joining material.

16. The method according to claim 14, wherein the collective board includes insulating layers, ground electrodes, and signal electrodes.

17. The method according to claim 16, wherein the ground electrodes and the signal electrodes are provided on the same ones of the insulating layers.

18. The method according to claim 16, wherein one of the ground electrodes is frame-shaped and surrounds the outer peripheral edge of the module board.

19. The method according to claim 1, wherein the electronic components include at least one of a semiconductor, a capacitor, an inductor and a resistor.

20. The method according to claim 16, wherein the plurality of electronic components are connected to the signal electrodes to define an electronic circuit.
